(19) United States
(12) Patent Application Publication
(10) Pub. No.: US 2026/0283022 A1
(43) Pub. Date: Sep. 17, 2026

(54) SEMICONDUCTOR DEVICE

(71) Applicants: KABUSHIKI KAISHA TOSHIBA, Kawasaki-shi (JP); TOSHIBA ELECTRONIC DEVICES & STORAGE CORPORATION, Kawasaki-shi (JP)

(72) Inventors: Eitaro MIYAKE, Tachikawa Tokyo (JP); Jia LIU, Yokohama Kanagawa (JP)

(73) Assignees: KABUSHIKI KAISHA TOSHIBA, Kawasaki-shi (JP); TOSHIBA ELECTRONIC DEVICES & STORAGE CORPORATION, Kawasaki-shi (JP)

(21) Appl. No.: 19/362,599

(22) Filed: Oct. 20, 2025

(30) Foreign Application Priority Data
Mar. 17, 2025 (JP) 2025-042038

(51) Int. Cl. H01L 23/00; H01L 25/16

(52) U.S. Cl. CPC H10W 90/00; H10W 72/07354; H10W 72/347; H10W 72/884; H10W 90/733; H10W 90/734; H10W 90/754

(57) ABSTRACT

According to an embodiment, a semiconductor device includes a first semiconductor chip and a second semiconductor chip. The first semiconductor chip and the second semiconductor chip each have a first electrode and a second electrode. The first electrode of the first semiconductor chip and the first electrode of the second semiconductor chip face each other and are arranged with a conductive connector sandwiched therebetween. The second electrodes are electrically connected to external electrodes externally exposed and spaced apart from each other.

### CROSS-REFERENCE TO RELATED APPLICATION

This application is based upon and claims the benefit of priority from Japanese Patent Application No. 2025-042038, filed on Mar. 17, 2025; the entire contents of which are incorporated herein by reference.

### FIELD

Embodiments described herein relate generally to a semiconductor device.

### BACKGROUND

There is a semiconductor device in which a semiconductor relay is used as a signal transfer means and a semiconductor chip such as a metal oxide semiconductor field effect transistor (hereinafter referred to as a MOSFET) is used as an output switching element in a semiconductor relay.

In the above-described semiconductor device, an effective means for improving the passing characteristics of the high-frequency semiconductor relay is to shorten a length of a connection portion and increase a cross-sectional area of the connection portion in an electrical connection between two semiconductor chips. Conventionally, wires have often been used as the connection portion in the electrical connection between the two semiconductor chips. However, it is not easy to shorten the length and increase the cross-sectional area.

### BRIEF DESCRIPTION OF THE DRAWINGS

FIG. 1 is a schematic plan view of a semiconductor device according to a first embodiment.

FIG. 2 is a cross-sectional view along II-II in FIG. 1.

FIG. 3 is a +X side view of FIG. 1.

FIG. 4 is a circuit diagram showing a circuit configuration of the semiconductor device according to the first embodiment.

FIG. 5 is a schematic plan view of a semiconductor device according to a second embodiment.

FIG. 6 is a cross-sectional view along II-II in FIG. 5.

### DETAILED DESCRIPTION

According to an embodiment, a semiconductor device includes a first semiconductor chip and a second semiconductor chip. The first semiconductor chip and the second semiconductor chip each have a first electrode and a second electrode. The first electrode of the first semiconductor chip and the first electrode of the second semiconductor chip face each other and are arranged with a conductive connector sandwiched therebetween. The second electrodes are electrically connected to external electrodes externally exposed and spaced apart from each other.

Hereinafter, a semiconductor device according to an embodiment will be described with reference to the drawings. In the following description, constituent elements having the same or similar functions are denoted by the same reference signs. Also, redundant descriptions of these constituent elements may be omitted.

Moreover, in each of the following embodiments, when constituent elements (e.g., circuits, wiring, various types of voltages and signals, and the like) denoted by reference signs accompanied by numerals/alphabetic letters for distinction do not need to be distinguished from each other, reference signs whose numerals/alphabetic letters are omitted may be used.

### First Embodiment

A configuration of a first embodiment of a semiconductor device will be described below.

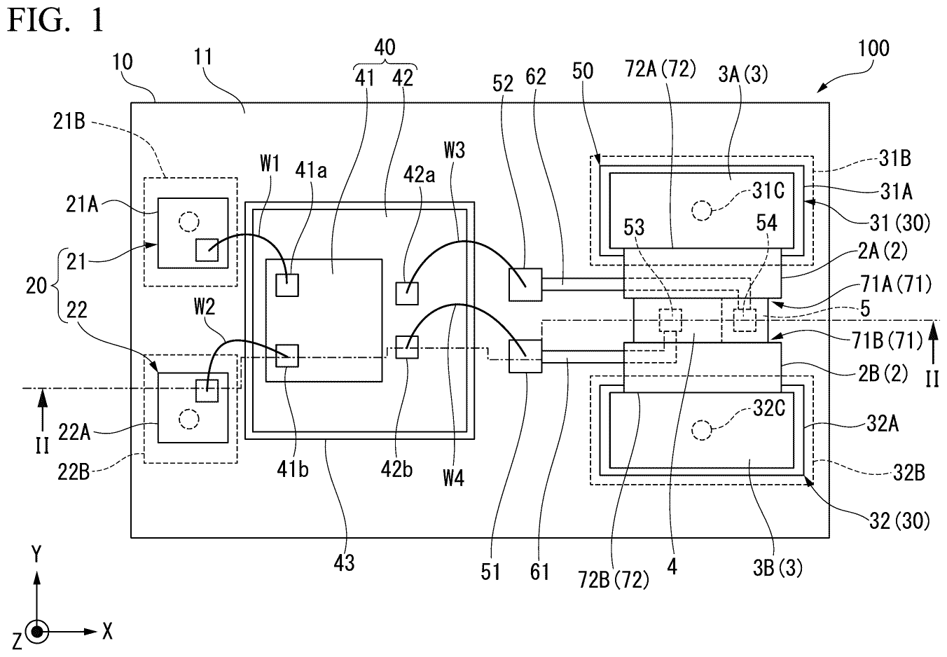

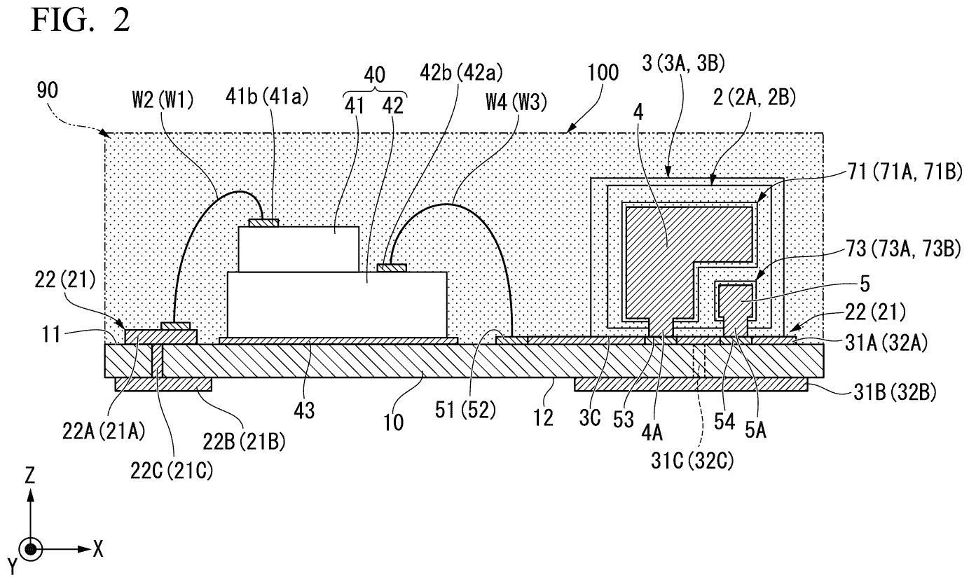

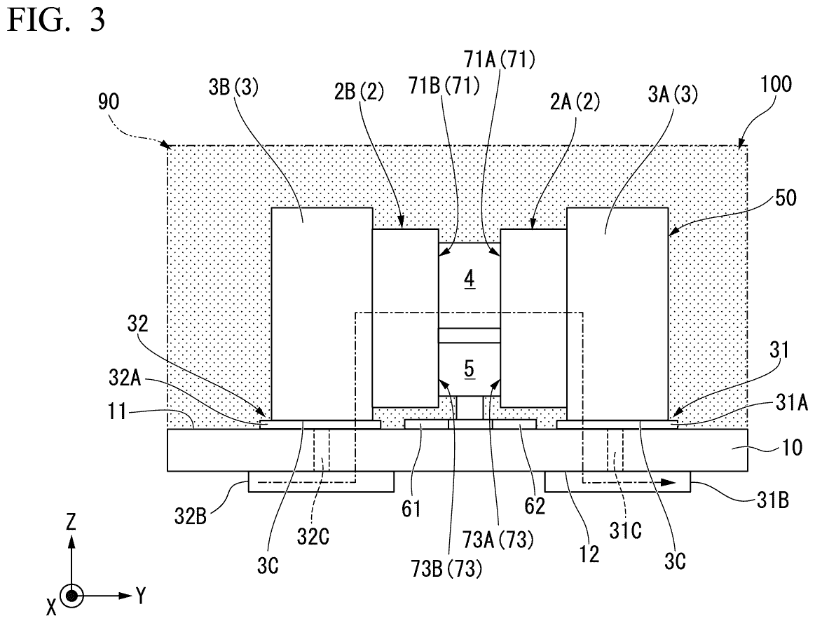

FIG. 1 is a schematic plan view of a semiconductor device 100 according to an embodiment. FIG. 2 is a cross-sectional view along II-II in FIG. 1. FIG. 3 is a +X side view in FIG. 1.

As shown in FIGS. 1 to 3, the semiconductor device 100 includes an insulating substrate (a substrate) 10, a transfer portion 40, a stack body 50 including a semiconductor chip 2, and a sealing resin body 90.

The insulating substrate 10 has a rectangular shape and examples thereof include a flexible substrate (flexible printed circuits (FPC)), a glass epoxy resin substrate, and the like. The insulating substrate 10 has a first surface 11 on which the stack body 50 is arranged and a second surface 12 on the opposite side of the first surface 11 in a thickness direction.

In an XYZ coordinate system shown in each drawing, a Z direction is defined as a thickness direction of the insulating substrate 10 and an up-down direction. In the Z direction, the first surface 11 side is a positive side (+Z side) and the second surface 12 side is a negative side (−Z side). Moreover, a positive side of the Z direction may be referred to as an “upper side” and a negative side of the Z direction may be referred to as a “lower side.” Moreover, as seen from above, a direction parallel to a direction in which the transfer portion 40 and the stack body 50 are arranged (a left-right direction in FIG. 1) is referred to as an X direction. A direction perpendicular to both the X direction and the Z direction (the up-down direction in FIG. 1) is referred to as a Y direction. In addition, the up-down direction, the upper side, and the lower side are names used simply for explanation and do not limit an actual positional relationship and direction.

The insulating substrate 10 has an input terminal portion 20, an output terminal portion 30, a pad portion 43, a first pad portion 51, a second pad portion 52, a third pad portion 53, a fourth pad portion 54, first wiring 61, and second wiring 62.

The input terminal portion 20 has, for example, a first terminal portion 21 and a second terminal portion 22. The first terminal portion 21 is arranged on the +Y side of the center of the insulating substrate 10 near the end of the −X side in the Y direction. The second terminal portion 22 is arranged on the −Y side of the center of the insulating substrate 10 near the end of the −X side in the Y direction.

The first terminal portion 21 has a pad portion 21A arranged on the first surface 11 and an input terminal 21B arranged on the second surface 12 and connected to the pad portion 21A by a via 21C. The second terminal portion 22 has a pad portion 22A arranged on the first surface 11 and an input terminal 22B arranged on the second surface 12 and connected to the pad portion 22A by a via 22C.

The output terminal portion 30 has, for example, a third terminal portion 31 and a fourth terminal portion 32. The third terminal portion 31 is arranged on the +Y side of the center of the insulating substrate 10 near the end of the +X side in the Y direction. The fourth terminal portion 32 is arranged on the −Y side of the center of the insulating substrate 10 near the end on the +X side in the Y direction.

The third terminal portion 31 has a pad portion (a connection pad) 31A arranged on the first surface 11 and an output terminal (an external electrode) 31B arranged on the second surface 12 and connected to the pad portion 31A by a via 31C. The fourth terminal portion 32 has a pad portion (a connection pad) 32A arranged on the first surface 11 and an output terminal (an external electrode) 32B arranged on the second surface 12 and connected to the pad portion 32A by a via 32C.

The pad portion 43 is arranged between the input terminal portion 20 and the first and second pad portions 51 and 52 on the first surface 11. The pad portion 43 is arranged below the transfer portion 40. Details of the transfer portion 40 will be described below.

The first pad portion 51 and the second pad portion 52 are arranged between the transfer portion 40 and the stack body 50 on the first surface 11. The positions of the first pad portion 51 and the second pad portion 52 in the X direction are, for example, the same. The first pad portion 51 is spaced apart from the second pad portion 52 on the −Y side. As an example, the first pad portion 51 is arranged on the −Y side of the center of the insulating substrate 10 in the Y direction. As an example, the second pad portion 52 is arranged on the +Y side of the center of the insulating substrate 10 in the Y direction.

The third pad portion 53 and the fourth pad portion 54 are arranged in a region where the stack body 50 is arranged. The third pad portion 53 and the fourth pad portion 54 are at the same position in the Y direction. The third pad portion 53 is spaced apart from the fourth pad portion 54 on the −X side. Details of the third pad portion 53 and the fourth pad portion 54 will be described below.

The first wiring 61 is arranged on the first surface 11, extends from the first pad portion 51 to the +X side, and is connected to the third pad portion 53. The second wiring 62 is arranged on the first surface 11, extends from the second pad portion 52 to the +X side, and is connected to the fourth pad portion 54. A control signal, which will be described below, is output from the light-receiving element 42 to the first wiring 61 and the second wiring 62. Details of the first wiring 61 and the second wiring 62 will be described below.

Conductive regions of the input terminal portion 20, the output terminal portion 30, the pad portion 43, the first pad portion 51, the second pad portion 52, the third pad portion 53, the fourth pad portion 54, the first wiring 61, and the second wiring 62 can be made of Cu foil provided on the insulating substrate 10, a plating layer of Ni, Au, or the like laminated thereon, and the like.

The semiconductor device 100 according to the embodiment is, for example, a photo relay. In this case, the transfer portion 40 includes an optical coupling device. An input voltage for controlling the photo relay is applied to the transfer portion 40 as a control signal via input terminals 21B and 22B, which are external connection terminals. The transfer portion 40 transfers the input control signal as an electrical signal to the semiconductor chip 2 in an insulated manner.

The transfer portion 40 includes a light-emitting element 41 and a light-receiving element 42. The light-emitting element 41 is, for example, a light-emitting diode (LED). The light-emitting element 41 is adhered to an upper surface of the light-receiving element 42 via an adhesive layer (not shown) having light transferring and insulating properties.

The light-receiving element 42 is adhered to the pad portion 43 via, for example, a silver-based bonding material such as silver paste or sintered silver, or a metallic conductive member such as solder. For example, a photodiode array (PDA), a phototransistor, a light receiving IC, and the like can be used as the light-receiving element 42. In the semiconductor device 100 of the embodiment, a photodiode array is used as the light-receiving element 42.

The first terminal portion 21 of the input terminal portion 20 is electrically connected to a cathode pad portion 41a of the light-emitting element 41 via a bonding wire W1. The second terminal portion 22 of the input terminal portion 20 is electrically connected to the anode pad portion 41b of the light-emitting element 41 via a bonding wire W2.

A pad portion 42a of the light-receiving element 42 is electrically connected to the second pad portion 52 via a bonding wire W3. A pad portion 42b of the light-receiving element 42 is electrically connected to the first pad portion 51 via a bonding wire W4.

The stack body 50 has a semiconductor chip 2, electrode parts 3 (3A and 3B), a conductive connector 4, and a second conductive connector 5. The semiconductor chip 2 includes a first semiconductor chip 2A and a second semiconductor chip 2B. The stack body 50 has a configuration in which the first semiconductor chip 2A and the electrode part 3A, and the second semiconductor chip 2B and the electrode part 3B are sequentially arranged on both sides in the Y direction, with the conductive connector 4 and the second conductive connector 5 at the center, and are integrated together. The parts constituting the stack body 50 are bonded via, for example, a silver-based bonding material such as silver paste or sintered silver or a metallic conductive member such as solder.

The first semiconductor chip 2A and the second semiconductor chip 2B are rectangular as seen in the Y direction. The first semiconductor chip 2A is spaced from the second semiconductor chip 2B in the Y direction. The first semiconductor chip 2A is located on the +Y side and the second semiconductor chip 2B is located on the −Y side. The first semiconductor chip 2A and the second semiconductor chip 2B are semiconductor elements. The first semiconductor chip 2A and the second semiconductor chip 2B are, for example, field effect transistors. As a more specific example, the first semiconductor chip 2A and the second semiconductor chip 2B are MOSFETs (for example, power MOSFETs). The first semiconductor chip 2A and the second semiconductor chip 2B are used to control the transfer of a signal of a photo relay, which will be described below. The signal transferred by the photo relay may be a DC signal or an AC signal.

The semiconductor chip 2 has a first electrode 71, a second electrode 72, and a third electrode 73. The first semiconductor chip 2A has a first electrode 71A, a second electrode 72A, and a third electrode 73A. The second semiconductor chip 2B has a first electrode 71B, a second electrode 72B, and a third electrode 73B. The first electrode 71A of the first semiconductor chip 2A and the first electrode 71B of the second semiconductor chip 2B face each other in the Y direction.

As shown in FIG. 2, as seen from the −Y side, the first electrode 71A has an L shape having a horizontal portion extending in the X direction and a vertical portion extending from the end of the −X side of the horizontal portion to the −Z side. Although not shown, the first electrode 71B has an L shape that is linearly symmetrical in opposition to the first electrode 71A in the Y direction. The first electrodes 71A and 71B are arranged facing each other without being offset from each other in an XZ plane.

The third electrode 73A is arranged farther away from the horizontal portion of the first electrode 71A on the −Z side and farther away from the vertical portion on the +X side. As seen from the −Y side, the third electrode 73A has a rectangular shape. Although not shown, the third electrode 73B has a rectangular shape that is linearly symmetrical in opposition to the third electrode 73A in the Y direction.

The second electrode 72A is the +Y side surface of the first semiconductor chip 2A. The second electrode 72B is the −Y side surface of the second semiconductor chip 2B. The first electrode 71 is a source electrode of the semiconductor chip 2 as an example. The second electrode 72 is a drain electrode of the semiconductor chip 2 as an example. The third electrode 73 is a gate electrode of the semiconductor chip 2 as an example.

The electrode parts 3A and 3B constituting the electrode part 3 are rectangular prisms extending from the first surface 11 of the insulating substrate 10 to the +Z side. The surfaces of the electrode parts 3A and 3B facing the first semiconductor chip 2A and the second semiconductor chip 2B are electrically connected to the second electrodes 72A and 72B, respectively. The electrode parts 3A and 3B are electrically connected to the pad portions 31A and 32A at a connection surface 3C facing the −Z side. Therefore, the electrode parts 3A and 3B are electrically connected to the output terminals 31B and 32B, which are external electrodes, through the pad portions 31A and 32A and the vias 32C. That is, the third terminal portion 31 and the fourth terminal portion 32 of the output terminal portion 30 are connected to the drain electrodes of the first semiconductor chip 2A and the second semiconductor chip 2B, respectively.

As seen in the X direction, the connection surface 3C protrudes toward the insulating substrate 10 farther than the semiconductor chip 2. When the connection surface 3C protrudes toward the insulating substrate 10 farther than the semiconductor chip 2, the contact of the semiconductor chip 2 with the insulating substrate 10 is suppressed when the stack body 50 is mounted on the insulating substrate 10, such that it is possible to ensure the pressure resistance of the semiconductor chip 2.

The electrode parts 3A and 3B are larger than the semiconductor chip 2 in all directions intersecting the Y direction, which is a direction in which the first electrodes 71A and 71B face each other, including the normal direction of the connection surface 3C. Because the electrode part 3 is larger than the semiconductor chip 2 in all directions intersecting the Y direction, it is possible to prevent the side surface of the semiconductor chip 2 from contacting the insulating substrate 10.

The conductive connector 4 is conductive and is arranged between the first electrodes 71A and 71B facing each other. That is, the first electrodes 71A and 71B facing each other are arranged with the conductive connector 4 sandwiched therebetween. The conductive connector 4 is formed of, for example, copper or a copper alloy. As shown in FIG. 2, the cross section of the conductive connector 4 perpendicular to the Y direction is an L-shape similar to those of the first electrodes 71A and 71B. Although the conductive connector 4 is smaller than the first electrodes 71A and 71B for ease of understanding in FIG. 2, the conductive connector 4 may have the same size as the first electrodes 71A and 71B or may be larger than the first electrodes 71A and 71B.

When the conductive connector 4, which has an L-shaped cross section and has a larger cross-sectional area than the wire, is arranged between the first electrodes 71A and 71B, the electrical resistance of the electric current flowing between the first electrodes 71A and 71B is reduced, thereby improving the passing characteristics.

The second conductive connector 5 is conductive and is arranged between the third electrodes 73A and 73B facing each other. That is, the third electrodes 73A and 73B facing each other are arranged with the conductive second conductive connector 5 sandwiched therebetween. The second conductive connector 5 is formed of, for example, copper or a copper alloy. The cross section of the second conductive connector 5 perpendicular to the Y direction is a rectangular shape similar to those of the third electrodes 73A and 73B. Although the second conductive connector 5 is smaller than the third electrodes 73A and 73B for ease of understanding in FIG. 2, the second conductive connector 5 may have the same size as the third electrodes 73A and 73B or may be larger than the third electrodes 73A and 73B.

The conductive connector 4 has a first protrusion 4A. The first protrusion 4A is provided at a position facing the third pad portion 53 in the Z direction. The first protrusion 4A extends to the −Z side and is electrically connected to the third pad portion 53 and the first wiring 61 when the stack body 50 is mounted on the insulating substrate 10. The second conductive connector 5 has a second protrusion 5A. The second protrusion 5A is provided at a position facing the fourth pad portion 54 in the Z direction. The second protrusion 5A extends to the −Z side and is electrically connected to the fourth pad portion 54 and the second wiring 62 when the stack body 50 is mounted on the insulating substrate 10. The first protrusion 4A and the third pad portion 53 are adhered to the second protrusion 5A and the fourth pad portion 54 via, for example, a silver-based bonding material such as silver paste or sintered silver, or a metallic conductive member such as solder.

The first protrusion 4A and the third pad portion 53 are arranged on the −X side of the second protrusion 5A and the fourth pad portion 54. Therefore, the length of the first wiring 61 is shorter than that of the second wiring 62.

The light-receiving element 42 and the sources of the first semiconductor chip 2A and the second semiconductor chip 2B are electrically connected via the bonding wire W4, the first pad portion 51, the first wiring 61, the third pad portion 53, the first protrusion 4A, the conductive connector 4, and the first electrodes 71A and 71B. Thereby, an electrical signal (a control signal) from the light-receiving element 42 is input to the first electrodes 71A and 71B. Moreover, the light-receiving element 42 and the gates of the first semiconductor chip 2A and the second semiconductor chip 2B are electrically connected via the bonding wire W3, the second pad portion 52, the second wiring 62, the fourth pad portion 54, the second protrusion 5A, the second conductive connector 5, and the third electrodes 73A and 73B. Thereby, an electrical signal (a control signal) from the light-receiving element 42 is input to the third electrodes 73A and 73B.

The sealing resin body 90 covers the light-emitting element 41, the light-receiving element 42, the stack body 50 including the first semiconductor chip 2A and the second semiconductor chip 2B, and the first surface 11 of the insulating substrate 10 to protect the inside. The output terminal (external electrode) 31B and the output terminal (the external electrode) 32B are externally exposed. The sealing resin body 90 can be made of, for example, epoxy resin, polyimide resin, or other resin.

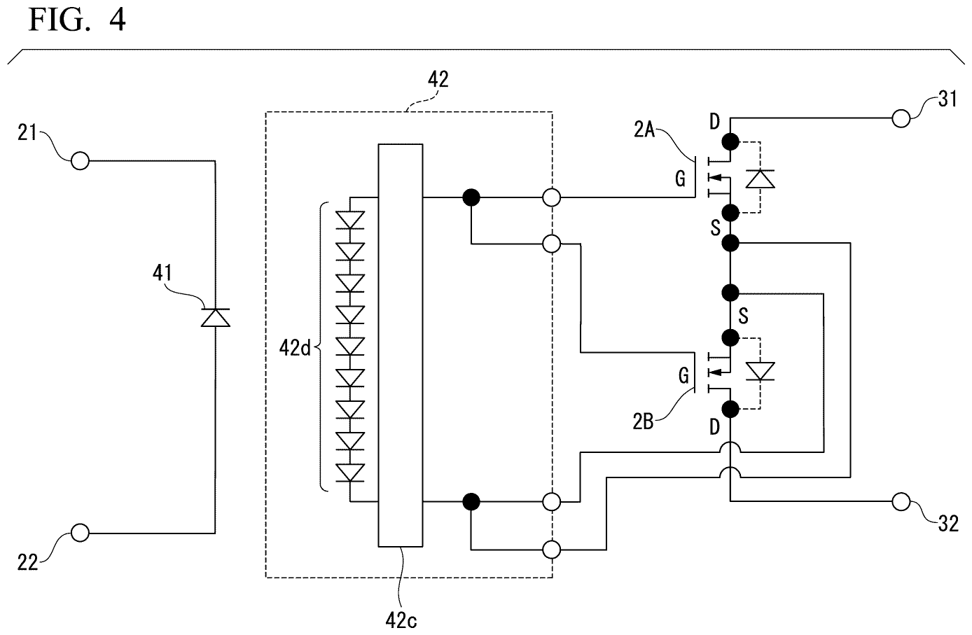

FIG. 4 is a circuit diagram showing the circuit configuration of the semiconductor device 100 of the first embodiment. The light-receiving element 42 can further include a control circuit 42c. The control circuit 42c is connected to the first electrode and the second electrode of a photodiode array 42d, respectively. With this configuration, a voltage can be supplied to the gates of the first semiconductor chip 2A and the second semiconductor chip 2B having a common source connection. Moreover, the control circuit 42c also includes a resistor and the like, and can shorten a falling time by causing a discharging process to be performed when the first semiconductor chip 2A and the second semiconductor chip 2B transition from ON to OFF.

The first semiconductor chip 2A and the second semiconductor chip 2B may be, for example, an n-channel enhancement type. In FIG. 4, gates G of the first semiconductor chip 2A and the second semiconductor chip 2B are connected to an anode of the photodiode array 42d. Moreover, sources S of the first and second semiconductor chips 2A and 2B are connected to a cathode of the photodiode array 42d, and drains D of the first and second semiconductor chips 2A and 2B are connected to the output terminals 31B and 32B.

When the optical signal is turned on, the first semiconductor chip 2A and the second semiconductor chip 2B are both turned on and connected to an external circuit including a power supply and a load via the output terminals 31B and 32B. On the other hand, when the optical signal is turned off, the first semiconductor chip 2A and the second semiconductor chip 2B are both turned off and cut off from the external circuit. The common source connection enables linear output and makes it easy to switch high-frequency signals.

When the optical signal is turned on, a main signal flows between the first semiconductor chip 2A and the second semiconductor chip 2B via the conductive connector 4 and the first electrodes 71A and 71B as shown by the dash-single dotted line in FIG. 3. At this time, signal reflection occurs in the first wiring 61 branched from the conductive connector 4. When the length of the first wiring 61 is long, the low frequency of the main signal is adversely affected. When the length of the first wiring 61 is short, the high frequency of the main signal is adversely affected. Therefore, when the length of the first wiring 61 is shorter than that of the second wiring 62, it is possible to suppress adverse effects on the low frequency of the main signal.

In the semiconductor device 100 of the embodiment, when the first semiconductor chip 2A and the second semiconductor chip 2B are mounted on the insulating substrate 10, the stack body 50 including the first semiconductor chip 2A and the second semiconductor chip 2B is once manufactured, and then the stack body 50 that has been manufactured is mounted on the insulating substrate 10.

Specifically, first, for example, the second semiconductor chip 2B, the conductive connector 4, the second conductive connector 5, the first semiconductor chip 2A, and the electrode part 3A are sequentially stacked from bottom to top, for example, via silver paste or the like, with respect to the electrode part 3B whose bonding surface with the second semiconductor chip 2B faces upward, and assembled into the stack body 50. In this case, the bonding surfaces between the parts are parallel to the horizontal plane.

The stack body 50 that has been assembled is mounted on the insulating substrate 10 in a state in which the connection surface 3C faces downward, the electrode parts 3A and 3B are electrically connected to the pad portions 31A and 32A, and the first protrusion 4A and the second protrusion 5A are electrically connected to the third pad portion 53 and the fourth pad portion 54.

When the parts of the stack body 50 are joined without fabricating the stack body 50 in advance, joining surfaces are vertical. In this case, there is a possibility that the silver paste or the like will drip onto the insulating substrate 10, resulting in a defective product. By mounting the stack body 50, which has been fabricated in advance, on the insulating substrate 10, the above-described failure can be suppressed.

According to the above-described first embodiment, because the first semiconductor chip 2A and the second semiconductor chip 2B have the first electrodes 71A and 71B and the second electrodes 72A and 72B, the first electrodes 71A and 71B face each other and are arranged with the conductive connector 4 sandwiched therebetween, and the second electrodes 72A and 72B are electrically connected to the output terminals 31B and 32B externally exposed and spaced apart from each other, a main signal flows between the first electrodes 71A and 71B of the first semiconductor chip 2A and the second semiconductor chip 2B via the conductive connector 4, which has a larger cross-sectional area and a smaller electrical resistance than a wire. Therefore, according to the first embodiment, it is possible to contribute to improving the passing characteristics of a semiconductor relay compatible with high frequencies.

According to the first embodiment, because the first semiconductor chip 2A and the second semiconductor chip 2B have the third electrodes 73A and 73B and the third electrodes 73A and 73B face each other with the second conductive connector 5 having conductivity sandwiched therebetween, an electric current can flow between the third electrodes 73A and 73B of the first semiconductor chip 2A and the second semiconductor chip 2B via the conductive connector 4, which has a larger cross-sectional area and a lower electrical resistance than a wire.

According to the first embodiment, because the connection surfaces 3C of the electrode parts 3A and 3B protrude toward the insulating substrate 10 farther than the first semiconductor chip 2A and the second semiconductor chip 2B, when the stack body 50 is mounted on the insulating substrate 10, the contact of the first semiconductor chip 2A and the second semiconductor chip 2B with the insulating substrate 10 is suppressed, such that it is possible to ensure the pressure resistance of the semiconductor chip 2.

According to the first embodiment, because the conductive connector 4 has the first protrusion 4A connected to the first wiring 61 and the second conductive connector 5 has the second protrusion 5A connected to the second wiring 62, it is possible to input an electrical signal (a control signal) from the light-receiving element 42 to the first electrodes 71A and 71B and the third electrodes 73A and 73B while suppressing the contact of the first semiconductor chip 2A and the second semiconductor chip 2B with the insulating substrate 10.

According to the first embodiment, the electrode parts 3A and 3B are larger than the first semiconductor chip 2A and the second semiconductor chip 2B in all directions intersecting the Y direction, such that it is possible to suppress the leakage of the electric current flowing through the first semiconductor chip 2A and the second semiconductor chip 2B to the electrode parts 3A and 3B.

According to the first embodiment, the first wiring 61 and the second wiring 62 are formed on the insulating substrate 10, and therefore can be formed during the process of forming other foils such as pads on the insulating substrate 10, which contributes to improving the efficiency of the manufacturing process.

According to the first embodiment, because the length of the first wiring 61 is shorter than the length of the second wiring 62, it is possible to suppress adverse effects on the low frequency of the main signal.

According to the first embodiment, because the stack body 50 in which the first semiconductor chip 2A, the second semiconductor chip 2B, and the electrode parts 3A and 3B are sequentially arranged on both sides between which the conductive connector 4 is sandwiched and are integrated is provided, and the connecting surface 3C of the stack body 50 is connected to the pad portions 31A and 32A, it is possible to suppress the occurrence of defective products caused by silver paste or the like dripping onto the insulating substrate 10.

### Second Embodiment of Semiconductor Device

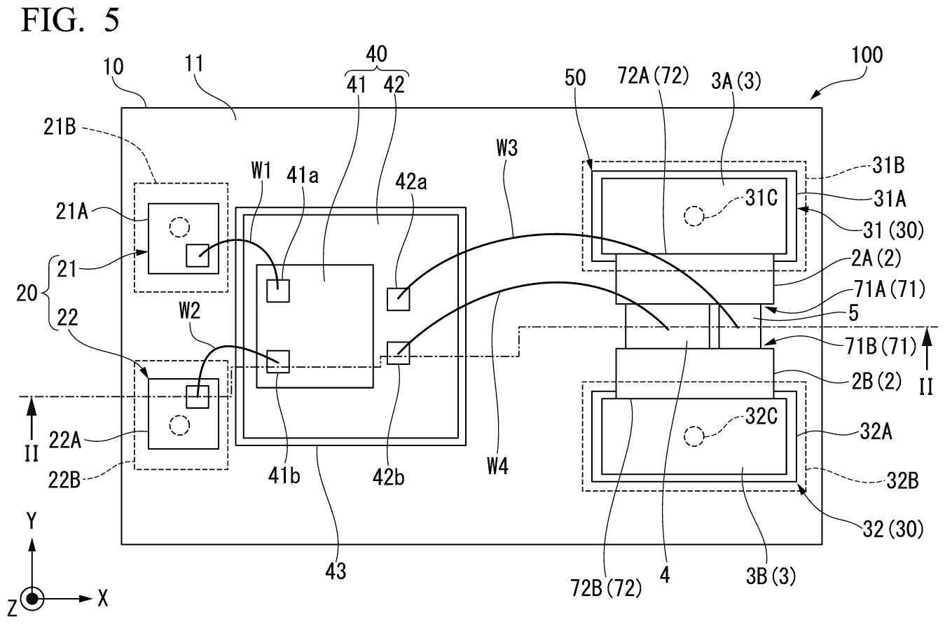

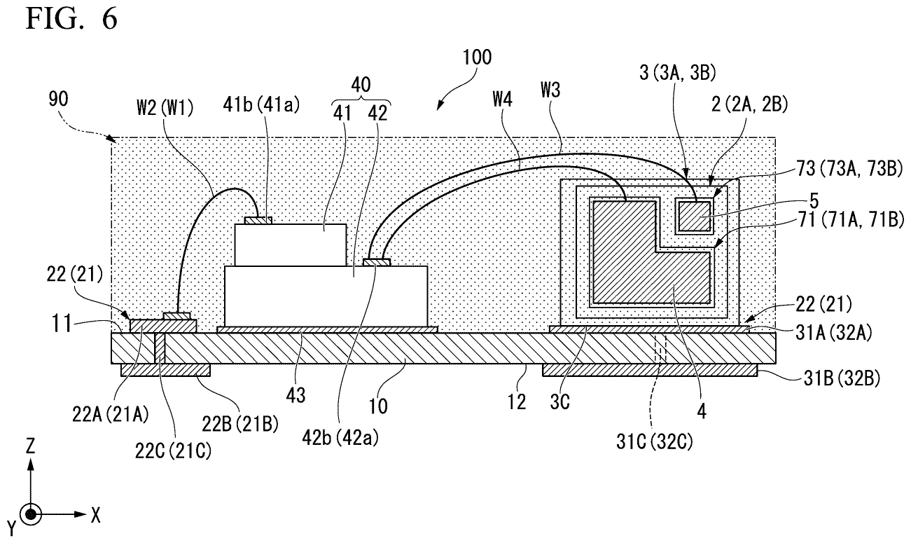

Next, a configuration of a second embodiment of the semiconductor device 100 will be described with reference to FIGS. 5 and 6. In these drawings, constituent elements identical to those of the first embodiment shown in FIGS. 1 to 4 are denoted by the same reference signs and description thereof will be omitted.

FIG. 5 is a partial cross-sectional view showing the semiconductor device 100 of the second embodiment. FIG. 6 is a cross-sectional view along II-II in FIG. 5. As shown in FIG. 6, the first electrodes 71A and 71B have an L shape having a horizontal portion extending in the X direction and a vertical portion extending from the end of the −X side of the horizontal portion to the +Z side as seen from the −Y side. The third electrodes 73A and 73B are spaced apart from each other on the +Z side of the horizontal portions of the first electrodes 71A and 71B, and on the +X side of the vertical portions. As seen from the −Y side, the third electrodes 73A and 73B are rectangular.

The cross section of the conductive connector 4 perpendicular to the Y direction has an L shape similar to those of the first electrodes 71A and 71B. The cross section of the second conductive connector 5 perpendicular to the Y direction has a rectangular shape similar to those of the third electrodes 73A and 73B. As shown in FIGS. 5 and 6, the second conductive connector 5 is exposed upward. The conductive connector 4 is exposed upward at a position on the −X side of the second conductive connector 5.

The bonding wire W4 serves as first wiring and electrically connects the pad portion 42b of the light-receiving element 42 to the conductive connector 4. The bonding wire W3 serves as second wiring and electrically connects the pad portion 42a of the light-receiving element 42 to the second conductive connector 5. A length of the bonding wire W4 is shorter than that of the bonding wire W3.

The light-receiving element 42 and the sources of the first and second semiconductor chips 2A and 2B are electrically connected via the bonding wire W4, the conductive connector 4, and the first electrodes 71A and 71B. Thereby, an electrical signal (a control signal) from the light-receiving element 42 is input to the first electrodes 71A and 71B via fewer conductive elements than in the first embodiment. Moreover, the light-receiving element 42 and gates of the first and second semiconductor chips 2A and 2B are electrically connected via the bonding wire W3, the second conductive connector 5, and the third electrodes 73A and 73B. Thereby, an electrical signal (a control signal) from the light-receiving element 42 is input to the third electrodes 73A and 73B via fewer conductive elements than in the first embodiment.

Specifically, the light-receiving element 42 is electrically connected to the first semiconductor chip 2A and the second semiconductor chip 2B by the bonding wires W3 and W4 without passing through conductive elements of the first pad portion 51, the second pad portion 52, the first wiring 61, the second wiring 62, the third pad portion 53, the fourth pad portion 54, the first protrusion 4A, and the second protrusion 5A.

Therefore, in the second embodiment, because it is not necessary to form the conductive elements on the insulating substrate 10, it is possible to contribute to improving manufacturing efficiency and reduce transfer loss of the control signal. Moreover, the length of the bonding wire W4 is shorter than that of the bonding wire W3, such that it is possible to suppress adverse effects on the low frequency of the main signal.

According to the second embodiment, in addition to obtaining functions and effects similar to those of the first embodiment, it is possible to contribute to improving manufacturing efficiency and reduce transfer loss of control signals.

According to at least one embodiment, because the first semiconductor chip 2A and the second semiconductor chip 2B have the first electrodes 71A and 71B and the second electrodes 72A and 72B, the first electrodes 71A and 71B face each other and are arranged with the conductive connector 4 sandwiched therebetween, and the second electrodes 72A and 72B are electrically connected to the output terminals 31B and 32B externally exposed and spaced apart from each other, a main signal flows between the first electrodes 71A and 71B of the first semiconductor chip 2A and the second semiconductor chip 2B via the conductive connector 4, which has a larger cross-sectional area and a smaller electrical resistance than a wire. Therefore, according to the first embodiment, it is possible to contribute to improving the passing characteristics of a semiconductor relay compatible with high frequencies.

Although an example of a configuration in which the first electrodes 71A and 71B are source electrodes and the second electrodes 72A and 72B are drain electrodes has been described in the above-described embodiment, the present invention is not limited to this configuration. When the first semiconductor chip 2A and the second semiconductor chip 2B are of the p-channel type, the first electrodes 71A and 71B may serve as drain electrodes and the second electrodes 72A and 72B may serve as source electrodes.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device comprising:
a first semiconductor chip; and
a second semiconductor chip,
wherein the first semiconductor chip and the second semiconductor chip each have a first electrode and a second electrode and the first electrode of the first semiconductor chip and the first electrode of the second semiconductor chip face each other and are arranged with a conductive connector sandwiched therebetween, and
wherein the second electrodes are electrically connected to external electrodes externally exposed and spaced apart from each other.

2. The semiconductor device according to claim 1,
wherein the first semiconductor chip and the second semiconductor chip each include an electrode part connected to the second electrode,
wherein the electrode part has a connection surface connected to a connection pad formed on a first surface of a substrate on which the first semiconductor chip and the second semiconductor chip are mounted, and
wherein the connection surface protrudes toward the substrate farther than the first semiconductor chip and the second semiconductor chip.

3. The semiconductor device according to claim 2,
wherein a normal direction of the connection surface intersects a facing direction in which the first electrodes face each other, and
wherein the electrode part is larger than the first semiconductor chip and t second semiconductor chip in all directions intersecting the facing direction.

4. The semiconductor device according to claim 2,
wherein a stack body in which the semiconductor chip and the electrode part are sequentially arranged on both sides between which a conductive connector is sandwiched and are integrated is provided, and
wherein the stack body has the connection surface connected to the connection pad.

5. The semiconductor device according to claim 2,
wherein the first semiconductor chip and the second semiconductor chip each have a third electrode, and
wherein the third electrodes are arranged to face each other with a conductive second conductive connector sandwiched therebetween.

6. The semiconductor device according to claim 5, comprising:
a first wiring which is electrically connected to the first electrode via the conductive connector and through which a control signal is output; and
a second wiring which is electrically connected to the third electrode via the second conductive connector and through which the control signal is output,
wherein a length of the first wiring is shorter than that of the second wiring.

7. The semiconductor device according to claim 6, wherein the first wiring and the second wiring are formed on the substrate.

8. The semiconductor device according to claim 7,
wherein the conductive connector has a first protrusion,
wherein the second conductive connector has a second protrusion,
wherein the first protrusion is connected to the first wiring, and
wherein the second protrusion is connected to the second wiring.

9. The semiconductor device according to claim 6, comprising a transfer portion electrically connected to the first electrode and the third electrode and configured to transfer the input control signal as an electric signal in an insulated manner.

10. The semiconductor device according to claim 9,
wherein the transfer portion includes an optical coupling device, and
wherein the first semiconductor chip and the second semiconductor chip include a transistor.
